(19) United States
(12) Patent Application Publication
(10) Pub. No.: US 2007/0182499 A1
(43) Pub. Date: Aug. 9, 2007

(54) Oscillation circuit

(76) Inventors: Katsushi Wakai, Shiga (JP); Ichiro Yamane, Kyoto (JP); Toshifumi Hamaguchi, Osaka (JP); Kazuhisa Raita, Kyoto (JP)

Correspondence Address: MCDERMOTT WILL & EMERY LLP, 600 13TH STREET, NW, WASHINGTON, DC, 20005-3096, US

(21) Appl. No.: 11/703,647

(22) Filed: Feb. 8, 2007

(30) Foreign Application Priority Data
Feb. 9, 2006 (JP) 2006-032251
Dec. 26, 2006 (JP) 2006-350262

(51) Int. Cl. H03B 5/20

(52) U.S. Cl. 331/135

(57) ABSTRACT

A first comparator outputs a first signal indicative that a voltage determined according to the amount of charge stored in a first capacitor has reached a first reference voltage. A second comparator outputs a second signal indicative that a voltage determined according to the amount of charge stored in a second capacitor has reached a second reference voltage. An RS flip flop circuit is shifted to a set state by one of the first signal and the second signal and shifted to a reset state by the other signal. When the RS flip flop circuit is in the set state, the first capacitor is in a charge state, and the second capacitor is in a discharge state. When the RS flip flop circuit is in the reset state, the first capacitor is in a discharge state, and the second capacitor is in a charge state.

### CROSS-REFERENCE TO RELATED APPLICATIONS

This application claims priority under 35 U.S.C. §119(a) on Japanese Patent Application No. 2006-032251 filed on Feb. 9, 2006 and Japanese Patent Application No. 2006-350262 filed on Dec. 26, 2006, the entire contents of which are hereby incorporated by reference.

### BACKGROUND OF THE INVENTION

1. Field of the Invention

The present invention relates to an oscillation circuit for supplying a signal with stable cycles to a semiconductor integrated circuit, or the like.

2. Description of the Prior Art

In recent years, the semiconductor integrated circuit has experienced process miniaturization to result in low operation voltage, so that errors readily occur due to noise. Thus, a semiconductor integrated circuit (e.g., microcomputer) resistant to noise has been demanded.

A known example of the conventional oscillation circuits is an oscillation circuit for generating a triangular-wave oscillation output using a toggle flip flop (see, for example, Japanese Laid-Open Patent Publication No. 5-226984).

A triangular-wave oscillation circuit which has a structure shown in FIG. 2 of Japanese Laid-Open Patent Publication No. 5-226984 is now described.

When the switch 102 is closed, the capacitor 105 is charged by a current which is generated by the constant current source 101.

When the switch 102a is closed, the capacitor 105a is charged by a current which is generated by the constant current source 101a.

The switch 102 is closed when output signal Q of the toggle flip flop 23 is at high level but is open when output signal Q is at low level.

The switch 102a is closed when output signal bar-Q (/Q) of the toggle flip flop 23 is at high level but is open when output signal Q is at low level.

The comparator 21 outputs high-level output signal CM when output voltage V_{O} of the capacitor 105 is higher than reference voltage V_{R1} and when output voltage bar-V_{O} (/V_{O}) of the capacitor 105a is higher than reference voltage V_{R1}.

When high-level output signal CM is input to the toggle flip flop 23, both output signal Q and output signal bar-Q are inverted.

With the above structure, when the switch 22 is closed to connect with the node f, the waveforms of output signal CM, output signal Q, output signal bar-Q, output voltage bar-V_{O} and output voltage V_{O} are as shown in, for example, FIG. 3 of Japanese Laid-Open Patent Publication No. 5-226984.

However, in the above-described conventional oscillation circuit, the cycles of output signal Q readily become unstable due to noise. For example, when output voltage V_{O} irregularly fluctuates around reference voltage V_{R1} while the capacitor 105 is charged, output signal CM accordingly rises several times, so that at every rising of output signal CM, output signal Q of the toggle flip flop 23 is inverted. In the example of FIG. 9, during the period from time A to time B, output signal Q transitions to high level due to noise in the midst of the period, though it should have been low level throughout the period. As a result, the phases of the waveforms of output signal Q and output signal bar-Q are shifted by about a half cycle from the desired phases of these signals with stable cycles.

### SUMMARY OF THE INVENTION

In view of the above circumstances, an objective of the present invention is to provide an oscillation circuit for supplying a signal with stable cycles even in the presence of noise.

To achieve the above objective, the first oscillation circuit according to an embodiment of the present invention includes:

first and second capacitors which are charged or discharged by a current generated by a constant current source;

a first comparator for comparing a first voltage which is determined according to the amount of charge stored in the first capacitor with a first reference voltage to output a first signal indicative that the first voltage has reached the first reference voltage;

a second comparator for comparing a second voltage which is determined according to the amount of charge stored in the second capacitor with a second reference voltage to output a second signal indicative that the second voltage has reached the second reference voltage;

an RS flip flop circuit which is shifted to a set state by one of the first signal and the second signal and shifted to a reset state by the other signal;

a first charge/discharge control circuit for controlling the first capacitor such that, when the RS flip flop circuit is in the set state, the first capacitor is in a charge state, and when the RS flip flop circuit is in the reset state, the first capacitor is in a discharge state; and

a second charge/discharge control circuit for controlling the second capacitor such that, when the RS flip flop circuit is in the reset state, the second capacitor is in a charge state, and when the RS flip flop circuit is in the set state, the second capacitor is in a discharge state.

In the first oscillation circuit, even when one of the first voltage and the second voltage fluctuates around the reference voltage due to noise, the number of inversions the output of the RS flip flop circuit experiences is equal to that counted in the absence of noise. Therefore, the RS flip flop circuit is capable of outputting a signal with stable cycles.

The second oscillation circuit according to an embodiment of the present invention includes:

first and second capacitors which are charged or discharged by a current generated by a constant current source;

a first comparator for comparing a first voltage which is determined according to the amount of charge stored in the first capacitor with a first reference voltage to output a first signal indicative that the first voltage has reached the first reference voltage;

a second comparator for comparing a second voltage which is determined according to the amount of charge stored in the second capacitor with a second reference voltage to output a second signal indicative that the second voltage has reached the second reference voltage;

a first RS flip flop circuit which is shifted to the set state when the first signal is output by the first comparator and which is shifted to the reset state when the second signal is output by the second comparator while the first RS flip flop circuit is in the set state;

a second RS flip flop circuit which is shifted to the set state when the second signal is output by the second comparator and which is shifted to the reset state when the first signal is output by the first comparator while the second RS flip flop circuit is in the set state;

a toggle flip flop circuit whose output is inverted when the first RS flip flop circuit shifts from the reset state to the set state and when the second RS flip flop circuit shifts from the reset state to the set state; and

a charge/discharge control circuit which selectively switches according to an output of the toggle flip flop circuit between a mode where the first capacitor is charged and the second capacitor is discharged and a mode where the first capacitor is discharged and the second capacitor is charged.

In the second oscillation circuit, even when the first voltage fluctuates around the reference voltage due to noise, the number of times the output of the first RS flip flop circuit rises is equal to that counted in the absence of noise. Likewise, even when the second voltage fluctuates around the reference voltage due to noise, the number of times the output of the second RS flip flop circuit rises is equal to that counted in the absence of noise. Therefore, the toggle flip flop circuit is capable of outputting a signal with stable cycles.

The third oscillation circuit according to an embodiment of the present invention is directed to the second oscillation circuit, wherein:

the set state is a state where an output is high level;

the reset state is a state where an output is low level;

the oscillation circuit further comprises
a first one-shot circuit which outputs a first pulse signal of high level when an output of the first RS flip flop circuit rises,
a second one-shot circuit which outputs a second pulse signal of high level when an output of the second RS flip flop circuit rises, and
a logical sum circuit which outputs a logical sum of the first pulse signal and the second pulse signal; and

the output of the toggle flip flop circuit is inverted at a rising or falling edge of the output of the logical sum circuit.

The fourth oscillation circuit according to an embodiment of the present invention includes:

any one of a charge-based first capacitor/comparator set and a discharge-based first capacitor/comparator set; and

any one of a charge-based second capacitor/comparator set and a discharge-based second capacitor/comparator set, wherein

the charge-based first capacitor/comparator set includes
a first capacitor which is charged by a current generated by a constant current source, and
a first comparator which outputs a first signal during a period extending from a time when a voltage determined according to the amount of charge stored in the first capacitor is increased to a first reference voltage by the charging of the first capacitor to a time when the voltage decreases to a second reference voltage which is lower than the first reference voltage,

the discharge-based first capacitor/comparator set includes
a first capacitor which is discharged by a current generated by a constant current source, and
a first comparator which outputs a first signal during a period extending from a time when a voltage determined according to the amount of charge stored in the first capacitor is decreased to a first reference voltage by the discharging of the first capacitor to a time when the voltage increases to a second reference voltage which is higher than the first reference voltage,

the charge-based second capacitor/comparator set includes
a second capacitor which is charged by a current generated by a constant current source, and
a second comparator which outputs a second signal during a period extending from a time when a voltage determined according to the amount of charge stored in the second capacitor is increased to a third reference voltage by the charging of the second capacitor to a time when the voltage decreases to a fourth reference voltage which is lower than the third reference voltage,

the discharge-based second capacitor/comparator set includes
a second capacitor which is discharged by a current generated by a constant current source, and
a second comparator which outputs a second signal during a period extending from a time when a voltage determined according to the amount of charge stored in the second capacitor is decreased to a third reference voltage by the discharging of the second capacitor to a time when the voltage increases to a fourth reference voltage which is higher than the third reference voltage, and

the oscillation circuit further comprises
a toggle flip flop circuit whose output is inverted every time any of the first signal and the second signal is output, and
a charge/discharge control circuit which selectively switches according to an output of the toggle flip flop circuit between a mode where the first capacitor is charged and the second capacitor is discharged and a mode where the first capacitor is discharged and the second capacitor is charged.

In the fourth oscillation circuit, even when noise occurs, effects of noise do not emerge in the output of the toggle flip flop circuit so long as the voltage determined according to the amount of charge stored in the first capacitor does not reach the second reference voltage or so long as the voltage determined according to the amount of charge stored in the second capacitor does not reach the fourth reference voltage. Therefore, the toggle flip flop circuit is capable of outputting a signal with stable cycles.

The fifth oscillation circuit according to an embodiment of the present invention is directed to any one of the first, second and fourth oscillation circuits, wherein the first and second capacitors are charged or discharged by a current generated by a common constant current source.

In the fifth oscillation circuit, the first and second capacitors are charged or discharged by equal currents, so that an oscillation signal having a duty ratio of 50% is obtained.

The sixth oscillation circuit according to an embodiment of the present invention is directed to the first oscillation circuit, wherein:

when charging the first capacitor, the first charge/discharge control circuit couples an end of the first capacitor with a constant current source, and when charging the second capacitor, the second charge/discharge control circuit couples an end of the second capacitor with a constant current source; and

when discharging the first capacitor, the first charge/discharge control circuit causes a short-circuit between both ends of the first capacitor, and when discharging the second capacitor, the second charge/discharge control circuit causes a short-circuit between both ends of the second capacitor.

The seventh oscillation circuit according to an embodiment of the present invention is directed to the second or fourth oscillation circuit, wherein:

the charge/discharge control circuit charges each of the first and second capacitors by coupling an end of the capacitor with a constant current source; and

the charge/discharge control circuit discharges each of the first and second capacitors by causing a short-circuit between both ends of the capacitor.

### BRIEF DESCRIPTION OF THE DRAWINGS

FIG. 1 is a block diagram showing the structure of an oscillation circuit according to embodiment 1.

FIG. 2 is a block diagram showing the structure of a first charge/discharge control circuit 109 and a second charge/discharge control circuit 110 according to embodiment 1.

FIG. 3 is a timing chart illustrating the operation of the oscillation circuit of embodiment 1.

FIG. 4 is a block diagram showing the structure of an oscillation circuit according to embodiment 2.

FIG. 5 is a block diagram showing the structure of one-shot circuits 204 and 205 according to embodiment 2.

FIG. 6 is a timing chart illustrating the operation of the oscillation circuit of embodiment 2.

FIG. 7 is a block diagram showing the structure of an oscillation circuit according to embodiment 3.

FIG. 8 is a timing chart illustrating the operation of the oscillation circuit of embodiment 3.

FIG. 9 is a timing chart illustrating the operation of a conventional oscillation circuit.

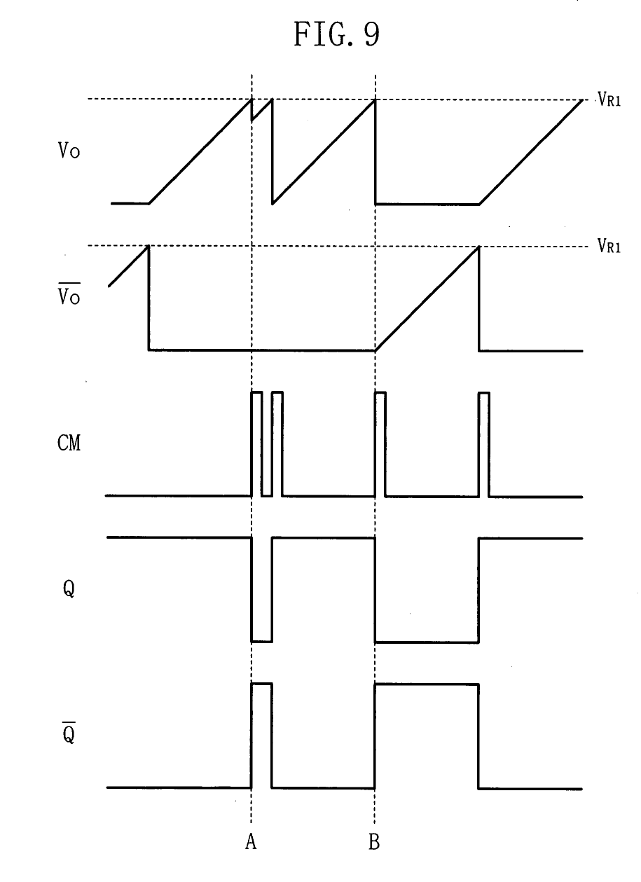

### DESCRIPTION OF THE PREFERRED EMBODIMENTS

Hereinafter, embodiments of the present invention will be described with reference to the drawings. In the embodiments described below, elements having like functions are denoted by the same reference numerals, and the descriptions of these elements are not redundantly provided.

### Embodiment 1

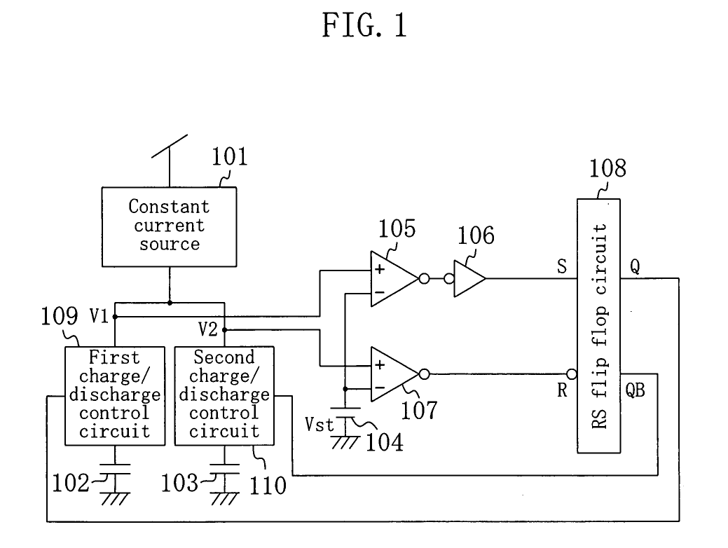

Referring to FIG. 1, an oscillation circuit of embodiment 1 includes a constant current source 101, a first capacitor 102, a second capacitor 103, a reference power supply 104, a comparator 105, an inverter 106, a comparator 107, an RS flip flop circuit 108, a first charge/discharge control circuit 109, and a second charge/discharge control circuit 110. The oscillation circuit of this embodiment is to be incorporated in a semiconductor integrated circuit.

The reference power supply 104 generates reference voltage Vst.

The comparator 105 compares voltage V1, which is determined according to the charge stored in the first capacitor 102, with reference voltage Vst. If voltage V1 is higher, the output of the comparator 105 is at low level. If reference voltage Vst is higher, the output of the comparator 105 is at high level.

The comparator 107 compares voltage V2, which is determined according to the charge stored in the second capacitor 103, with reference voltage Vst. If voltage V2 is higher, the output of the comparator 107 is at low level. If reference voltage Vst is higher, the output of the comparator 107 is at high level.

The RS flip flop circuit 108 is configured to be shifted to the set state by the high-level output of the inverter 106 (first signal) and shifted to the reset state by the low-level output of the comparator 107 (second signal). The RS flip flop circuit 108 outputs output signal Q and inverse output signal QB which is an inverse of output signal Q.

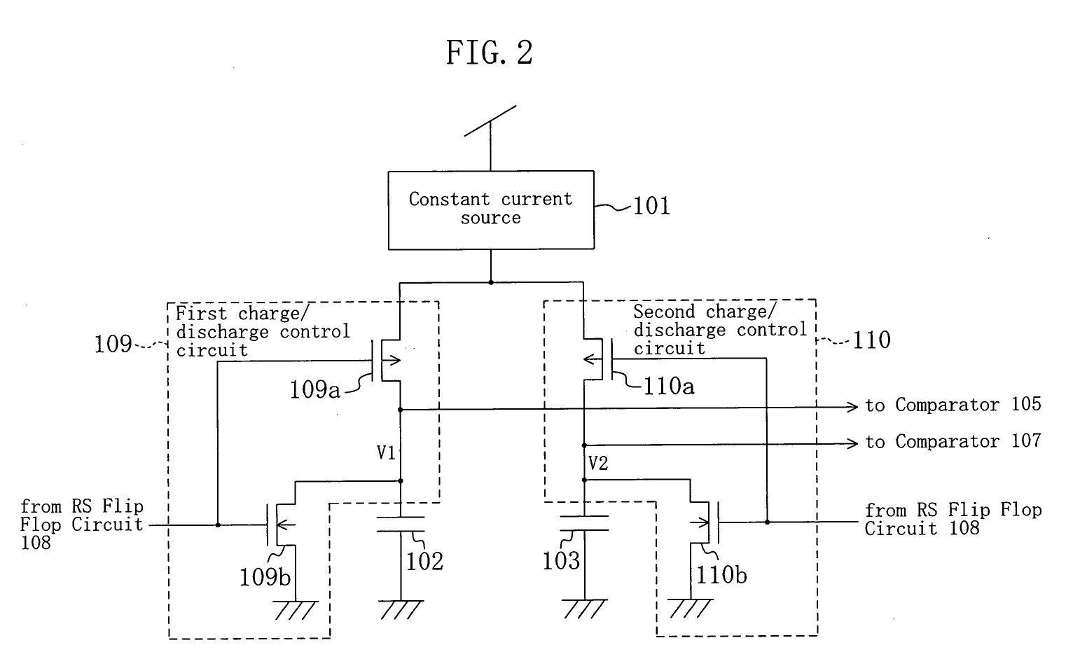

Referring to FIG. 2, the first charge/discharge control circuit 109 includes a PMOS transistor 109a and an NMOS transistor 109b. Output signal Q of the RS flip flop circuit 108 is input to the gates of these transistors. With such a structure, the first charge/discharge control circuit 109 controls supply of charge from the current source 101 to the first capacitor 102. More specifically, when output signal Q is at high level (when the RS flip flop circuit 108 is in the set state), the first charge/discharge control circuit 109 places the first capacitor 102 in the discharge state. When output signal Q is at low level (when the RS flip flop circuit 108 is in the reset state), the first charge/discharge control circuit 109 places the first capacitor 102 in the charge state.

Referring to FIG. 2, the second charge/discharge control circuit 110 includes a PMOS transistor 110a and an NMOS transistor 110b. Inverse output signal QB of the RS flip flop circuit 108 is input to the gates of these transistors. With such a structure, the second charge/discharge control circuit 110 controls supply of charge from the current source 101 to the second capacitor 103. More specifically, when inverse output signal QB is at high level (when the RS flip flop circuit 108 is in the reset state), the second charge/discharge control circuit 110 places the second capacitor 103 in the discharge state. When inverse output signal QB is at low level (when the RS flip flop circuit 108 is in the set state), the second charge/discharge control circuit 110 places the second capacitor 103 in the charge state.

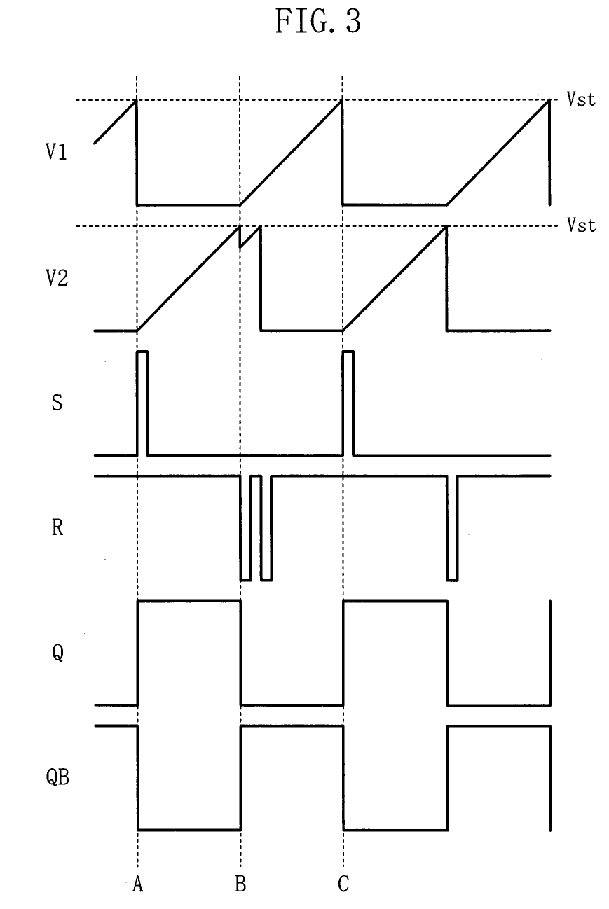

Next, the operation of the oscillation circuit having the above-described structure is described with reference to the timing chart of FIG. 3. The timing chart of FIG. 3 presents the waveforms of signals where voltage V2 exceeds reference voltage Vst due to noise in the period between time B and time C.

At time A of FIG. 3, a high-level signal is input to the S terminal of the RS flip flop circuit 108, so that output signal Q transitions from low level to high level, and inverse output signal QB transitions from high level to low level. The transition of output signal Q to high level causes the first charge/discharge control circuit 109 to operate such that charge stored in the first capacitor 102 is discharged to the ground side. Accordingly, voltage V1 of the first capacitor 102 decreases from high level to low level. Meanwhile, the transition of output signal QB to low level causes the second charge/discharge control circuit 110 to operate such that the second capacitor 103 is charged. Accordingly, voltage V2 of the second capacitor 103 increases along with the storage of charge in the second capacitor 103 by the charging operation.

Voltage V2 of the second capacitor 103 continues to be increased by the charging operation during the period from time A to time B at which voltage V2 exceeds reference voltage Vst. During the period between time A and time B, a signal input to the R terminal, i.e., the output of the comparator 107, is at high level. During this period, output signal Q of the RS flip flop circuit 108 is maintained at high level, and inverse output signal QB is maintained at low level. Voltage V1 of the first capacitor 102 starts decreasing at time A to reach low level and then stays at low level until time B.

At time B, voltage V2 of the second capacitor 103 exceeds reference voltage Vst, so that the output of the comparator 107, i.e., the comparison result, falls to low level. Accordingly, a low-level signal is input to the R terminal of the RS flip flop circuit 108, so that output signal Q of the RS flip flop circuit 108 transitions from high level to low level, and inverse output signal QB transitions from low level to high level. As a result, the second charge/discharge control circuit 110 operates such that charge stored in the second capacitor 103 is discharged to the ground side. Accordingly, voltage V2 of the second capacitor 103 decreases from high level to low level. Meanwhile, the transition of output signal Q to low level causes the first charge/discharge control circuit 109 to operate such that the first capacitor 102 is charged. Accordingly, voltage V1 of the first capacitor 102 increases along with the storage of charge in the first capacitor 102 by the charging operation.

Voltage V1 of the first capacitor 102 continues to be increased by the charging operation during the period from time B to time C at which voltage V1 exceeds reference voltage Vst. During the period between time B and time C, output signal Q of the RS flip flop circuit 108 is maintained at low level, and inverse output signal QB is maintained at high level. Voltage V2 of the second capacitor 103 starts decreasing at time B to reach low level and then stays at low level until time C.

Once a low-level signal is held in response to the input of the low-level signal to the R terminal, the output of the RS flip flop circuit 108 does not change till a high-level signal is input to the S terminal. Thus, as shown in FIG. 3, even if, during the period between time B and time C, voltage V2 exceeds reference voltage Vst due to noise and a low-level signal is input to the R terminal of the RS flip flop circuit 108, output signal Q and inverse output signal QB of the RS flip flop circuit 108 do not change.

At time C, voltage V1 of the first capacitor 102 exceeds reference voltage Vst, so that the output of the comparator 105, i.e., the comparison result, falls to low level. Accordingly, a high-level signal is input to the S terminal of the RS flip flop circuit 108.

The above-described operation during the period from time A to time C is repeated, whereby output signal Q and inverse output signal QB, which are oscillation signals, are obtained.

Thus, the oscillation circuit of this embodiment is capable of supplying output signal Q and inverse output signal QB with stable cycles without being affected by noise.

Further, a wider extent of noise can be neglected in respect of its effects as compared with a case where the effects of noise are avoided only by using a hysteresis-based comparator.

The oscillation circuit of this embodiment has a simple structure and therefore can be realized by a smaller number of components and consume a smaller circuit area. Such an oscillation circuit can readily be incorporated in a semiconductor integrated circuit.

### Embodiment 2

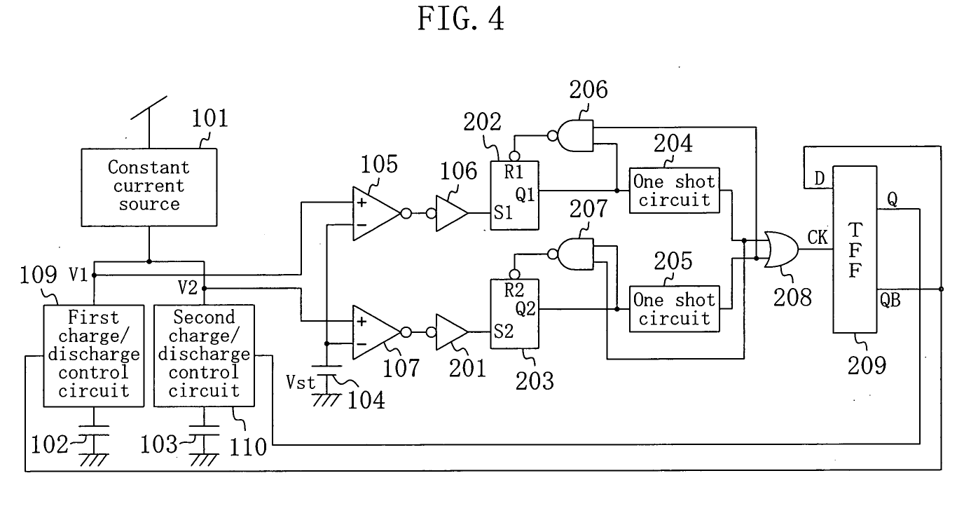

Referring to FIG. 4, an oscillation circuit of embodiment 2 includes a constant current source 101, a first capacitor 102, a second capacitor 103, a reference power supply 104, a comparator 105, an inverter 106, a comparator 107, a first charge/discharge control circuit 109, a second charge/discharge control circuit 110, an inverter 201, RS flip flop circuits 202 and 203 (first and second RS flip flop circuits), one-shot circuits 204 and 205 (first and second one-shot circuits), NAND circuits 206 and 207, an OR circuit 208 (logical sum circuit), and a toggle flip flop circuit 209.

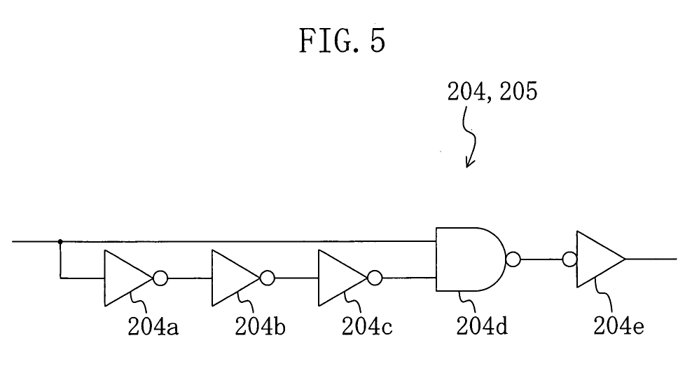

The one-shot circuits 204 and 205 each output a pulse having a predetermined width when the signal input thereto rises. Specifically, as shown in FIG. 5, the one-shot circuits 204 and 205 each include inverters 204a to 204c, NAND circuit 204d, and an inverter 204e. The inverters 204a to 204c delays the signal output from the RS flip flop circuit (202 or 203) by a sufficient amount of delay for the NAND circuit 204d to output a pulse having a required width. The delay amount can be increased by using an inverter of lower drivability.

The structure of the one-shot circuits 204 and 205 is not limited to that shown in FIG. 5. In the example of FIG. 5, the number of inverters provided before the NAND circuit 204d is three, but this embodiment is not limited thereto. Alternatively, buffers and inverters may be used in combination.

In the first charge/discharge control circuit 109, inverse output signal QB of the toggle flip flop circuit 209 is input to the gates of the PMOS transistor 109a and NMOS transistor 109b. In the second charge/discharge control circuit 110, output signal Q of the toggle flip flop circuit 209 is input to the gates of the PMOS transistor 110a and NMOS transistor 110b.

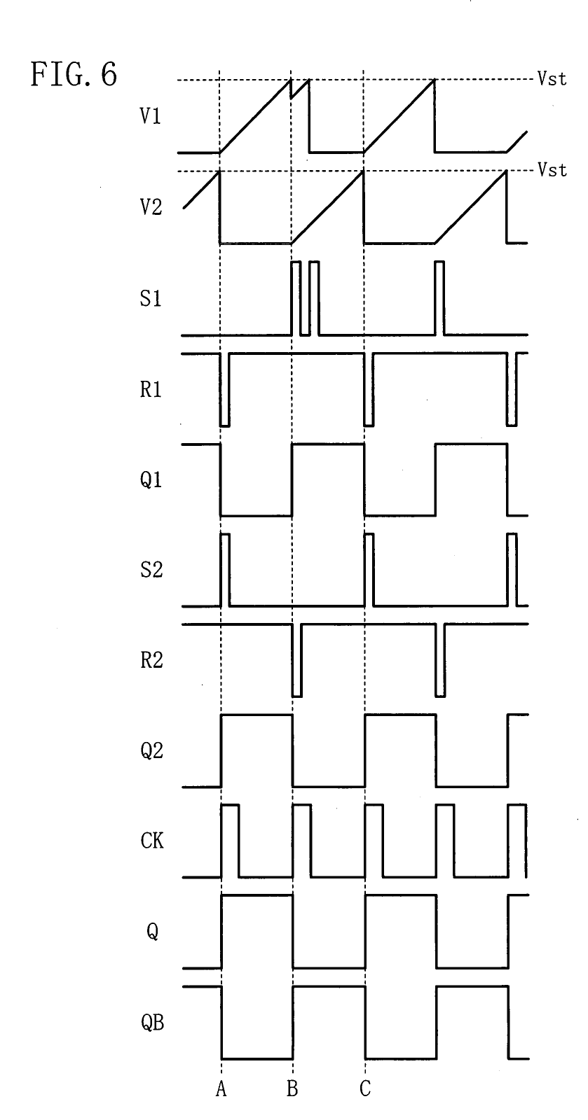

Next, the operation of the oscillation circuit having the above-described structure is described with reference to the timing chart of FIG. 6. The timing chart of FIG. 6 presents the waveforms of signals where voltage V2 exceeds reference voltage Vst due to noise in the period between time B and time C.

At time A of FIG. 6, signal CK output from the OR circuit 208 transitions to high level, so that output signal Q of the toggle flip flop circuit 209 transitions from low level to high level, and inverse output signal QB of the toggle flip flop circuit 209 transitions from high level to low level. The transition of output signal Q to high level causes the second charge/discharge control circuit 110 to operate such that charge stored in the second capacitor 103 is discharged to the ground side. Accordingly, voltage V2 of the second capacitor 103 falls from high level to low level. Meanwhile, the transition of output signal QB to low level causes the first charge/discharge control circuit 109 to operate such that the first capacitor 102 is charged. Accordingly, voltage V1 of the first capacitor 102 increases along with the storage of charge in the first capacitor 102 by the charging operation.

Voltage V1 of the first capacitor 102 continues to be increased by the charging operation during the period from time A to time B at which voltage V1 exceeds reference voltage Vst. During this period, output signal Q1 of the RS flip flop circuit 202 is maintained at low level, and output signal Q2 of the RS flip flop circuit 203 is maintained at high level. During the period from time A to time B, output signal Q of the toggle flip flop circuit 209 is maintained at high level, and inverse output signal QB is maintained at low level. Voltage V2 of the second capacitor 103 starts decreasing at time A to reach low level and then stays at low level until time B.

At time B, voltage V1 of the first capacitor 102 exceeds reference voltage Vst, so that the output of the comparator 105, i.e., the comparison result, falls to low level. The low-level output from the comparator 105 is inverted by the inverter 106, so that the high-level signal is input to the S1 terminal of the RS flip flop circuit 202. Accordingly, output signal Q1 of the RS flip flop circuit 202 transitions to high level. The transition of output signal Q1 to high level causes the one-shot circuit 204 to output a high-level pulse signal. Then, a high-level pulse signal from the OR circuit 208 is input as signal CK to a trigger input terminal of the toggle flip flop circuit 209. Since at this point in time output signal Q2 of the RS flip flop circuit 203 is high level, the output of the NAND circuit 207 is low level when the one-shot circuit 204 outputs a high-level pulse signal. The low-level signal output from the NAND circuit 207 is input to the R2 terminal of the RS flip flop circuit 203, so that output signal Q2 is inverted to low level.

At time B, a high-level pulse signal is input to the trigger input terminal of the toggle flip flop circuit 209, so that output signal Q of the toggle flip flop circuit 209 is inverted from high level to low level, and inverse output signal QB is inverted from low level to high level. The inversion of inverse output signal QB to high level causes the first charge/discharge control circuit 109 to operate such that charge stored in the first capacitor 102 is discharged to the ground side. Accordingly, voltage V1 of the first capacitor 102 falls from high level to low level. Meanwhile, the inversion of output signal Q to low level causes the second charge/discharge control circuit 110 to operate such that the second capacitor 103 is charged. Accordingly, voltage V2 of the second capacitor 103 increases along with the storage of charge in the second capacitor 103 by the charging operation.

Voltage V2 of the second capacitor 103 continues to be increased by the charging operation during the period from time B to time C at which voltage V2 exceeds reference voltage Vst. During the period from time B to time C, output signal Q of the toggle flip flop circuit 209 is maintained at low level, and inverse output signal QB is maintained at high level. Voltage V1 of the first capacitor 102 starts decreasing at time B to reach low level and then stays at low level until time C.

Once a high-level signal is held in response to the input of the high-level signal to the S1 terminal at time B, the output of the RS flip flop circuit 202 does not change till a low-level signal is input to the R1 terminal. Thus, as shown in FIG. 6, even if, during the period between time B and time C, voltage V1 exceeds reference voltage Vst due to noise and a high-level signal is input to the S1 terminal of the RS flip flop circuit 202, output signal Q1 of the RS flip flop circuit 202 does not change. Therefore, in this case, output signal Q and inverse output signal QB of the toggle flip flop circuit 209 also do not change.

At time C, voltage V2 of the second capacitor 103 exceeds reference voltage Vst, so that the output of the comparator 107, i.e., the comparison result, falls to low level. The low-level output of the comparator 107 is inverted by the inverter 201, so that a high-level signal is input to the S2 terminal of the RS flip flop circuit 203. Accordingly, output signal Q2 of the RS flip flop circuit 203 transitions to high level. The transition of output signal Q2 to high level causes the one-shot circuit 205 to output a high-level pulse signal. Then, a high-level pulse signal from the OR circuit 208 is input as signal CK to the trigger input terminal of the toggle flip flop circuit 209. Since at this point in time output signal Q1 of the RS flip flop circuit 202 is high level, the output of the NAND circuit 206 is low level when the one-shot circuit 205 outputs a high-level pulse signal. The low-level signal output from the NAND circuit 206 is input to the R1 terminal of the RS flip flop circuit 202, so that output signal Q1 is inverted to low level.

At time C, a high-level pulse signal is input as signal CK to the trigger input terminal of the toggle flip flop circuit 209, so that output signal Q of the toggle flip flop circuit 209 is inverted from low level to high level, and inverse output signal QB is inverted from high level to low level.

The above-described operation during the period from time A to time C is repeated, whereby output signal Q and inverse output signal QB, which are oscillation signals, are obtained.

Thus, the oscillation circuit of this embodiment is capable of supplying output signal Q and inverse output signal QB with stable cycles without being affected by noise.

### Embodiment 3

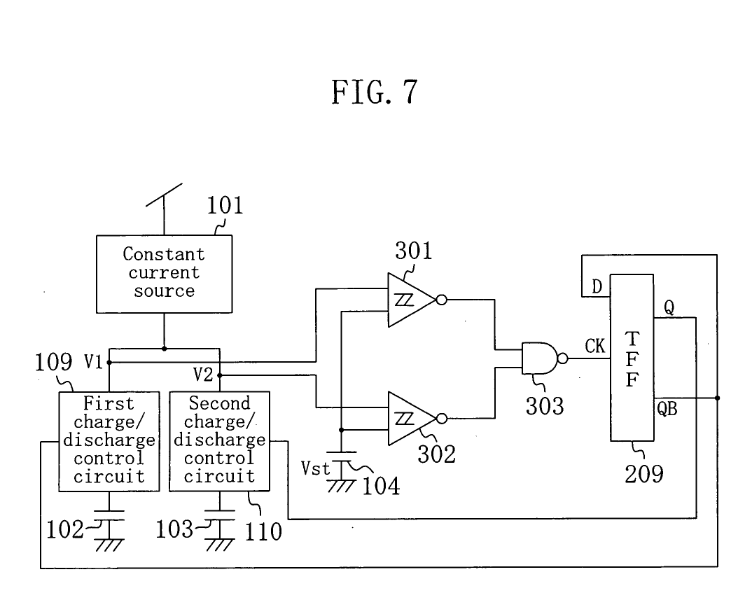

Referring to FIG. 7, an oscillation circuit of embodiment 3 includes a constant current source 101, a first capacitor 102, a second capacitor 103, a reference power supply 104, a first charge/discharge control circuit 109, a second charge/discharge control circuit 110, comparators 301 and 302 (Schmitt circuits), an NAND circuit 303, and a toggle flip flop circuit 209.

The comparator 301 (first comparator) outputs a low level signal during a period extending from a time when voltage V1 of the first capacitor 102 is increased by the charging operation to exceed Schmitt voltage Vsc (Schmitt voltage Vsc being defined as a voltage higher than reference voltage Vst by a predetermined width (Schmitt width)) to a time when voltage V1 is decreased to reference voltage Vst by the discharging operation. Other than this period, the comparator 301 outputs a high level signal.

The comparator 302 (second comparator) outputs a low level signal during a period extending from a time when voltage V2 of the second capacitor 103 in increased by the charging operation to exceed Schmitt voltage Vsc to a time when voltage V2 is decreased to reference voltage Vst by the discharging operation. Other than this period, the comparator 302 outputs a high level signal.

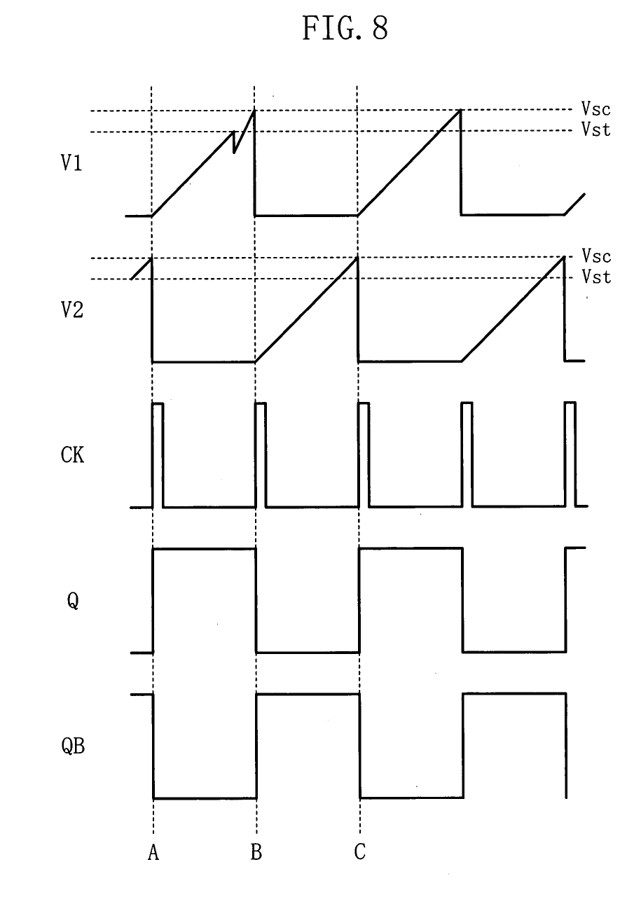

Next, the operation of the oscillation circuit having the above-described structure is described with reference to the timing chart of FIG. 8. The timing chart of FIG. 8 presents the waveforms of signals where voltage V1 exceeds reference voltage Vst due to noise in the period between time A and time B.

At time A of FIG. 8, signal CK output from the NAND circuit 303 transitions to high level, so that output signal Q of the toggle flip flop circuit 209 transitions from low level to high level, and inverse output signal QB of the toggle flip flop circuit 209 transitions from high level to low level. The transition of output signal Q to high level causes the second charge/discharge control circuit 110 to operate such that charge stored in the second capacitor 103 is discharged to the ground side. Accordingly, voltage V2 of the second capacitor 103 falls from high level to low level. Meanwhile, the transition of output signal QB to low level causes the first charge/discharge control circuit 109 to operate such that the first capacitor 102 is charged. Accordingly, voltage V1 of the first capacitor 102 increases along with the storage of charge in the first capacitor 102 by the charging operation.

Voltage V1 of the first capacitor 102 continues to be increased by the charging operation during the period from time A to time B at which voltage V1 exceeds reference voltage Vsc. During this period, output signal Q of the toggle flip flop circuit 209 is maintained at high level, and inverse output signal QB is maintained at low level. Voltage V2 of the second capacitor 103 starts decreasing at time A to reach low level and then stays at low level until time B.

At time B, voltage V1 of the first capacitor 102 exceeds voltage Vsc which is higher than reference voltage Vst by a predetermined width, so that the output of the comparator 301, i.e., the comparison result, falls to low level. Accordingly, signal CK output from the NAND circuit 303 transitions to high level.

The high-level signal CK is input to the trigger input terminal of the toggle flip flop circuit 209, so that output signal Q of the toggle flip flop circuit 209 is inverted from high level to low level, and inverse output signal QB is inverted from low level to high level. The inversion of inverse output signal QB to high level causes the first charge/discharge control circuit 109 to operate such that charge stored in the first capacitor 102 is discharged to the ground side. Accordingly, voltage V1 of the first capacitor 102 falls from high level to low level. Meanwhile, the inversion of output signal Q to low level causes the second charge/discharge control circuit 110 to operate such that the second capacitor 103 is charged. Accordingly, voltage V2 of the second capacitor 103 increases along with the storage of charge in the second capacitor 103 by the charging operation.

Even when voltage V1 irregularly fluctuates around reference voltage Vst due to noise at about time B as shown in FIG. 8, the effect of the irregular fluctuation does not emerge in output signal Q because, when voltage V1 is increasing, the comparator 301 compares voltage V1 with voltage Vsc which is higher than reference voltage Vst by a predetermined width (Vsc-Vst). That is, even when voltage V1 exceeds reference voltage Vst due to noise, a high-level pulse signal is not input to the trigger input terminal of the toggle flip flop circuit 209 before voltage V1 exceeds voltage Vsc.

Voltage V2 of the second capacitor 103 continues to be increased by the charging operation during the period from time B to time C at which voltage V2 exceeds voltage Vsc which is higher than reference voltage Vst by a predetermined width. During the period from time B to time C, output signal Q of the toggle flip flop circuit 209 is maintained at low level, and inverse output signal QB is maintained at high level. Voltage V1 of the first capacitor 102 starts decreasing at time B to reach low level and then stays at low level until time C.

At time C, voltage V2 of the second capacitor 103 exceeds voltage Vsc which is higher than reference voltage Vst by a predetermined width, so that the output of the comparator 302, i.e., the comparison result, falls to low level. Accordingly, signal CK output from the NAND circuit 303 transitions to high level.

The high-level signal CK is input to the trigger input terminal of the toggle flip flop circuit 209, so that output signal Q of the toggle flip flop circuit 209 is inverted from low level to high level, and inverse output signal QB is inverted from high level to low level.

The above-described operation during the period from time A to time C is repeated, whereby output signal Q and inverse output signal QB, which are oscillation signals, are obtained.

Thus, in the oscillation circuit of this embodiment, even if noise occurs, the noise does not affect output signal Q or inverse output signal QB so long as the noise does not cause voltage V1 or voltage V2 to exceed voltage Vsc which is higher than reference voltage Vst by a predetermined width. Therefore, the oscillation circuit of this embodiment is capable of supplying output signal Q and inverse output signal QB with more stable cycles as compared with the conventional circuit.

### Other Embodiments

Although in the oscillation circuits of the above-described embodiments both the first capacitor 102 and the second capacitor 103 are charged by the current source 101, the first capacitor 102 and the second capacitor 103 may be charged by different constant current sources.

Although in the oscillation circuits of the above-described embodiments each of the first capacitor 102 and the second capacitor 103 is discharged by causing a short-circuit between both ends, but it may be coupled with a constant current source at the time of discharge and discharged by a current generated by the constant current source.

Although in the oscillation circuits of the above-described embodiments the cycle of output signal Q is controlled based on the time required for charging the capacitor, but it may be controlled based on the time required for discharging the capacitor. Specifically, when the first capacitor 102 and the second capacitor 103 are discharged by a current flowing through the constant current source and the comparators 105 and 107 detect that any one of the voltages at the first capacitor 102 and the second capacitor 103 is lower than a predetermined reference voltage, output signal Q and inverse output signal QB may be inverted. Further, even in the case where the cycle of output signal Q is controlled based on the time required for discharging the capacitor, the hysteresis of the comparator can be utilized as in the oscillation circuit of embodiment 3. Specifically, the reference voltage of the comparators 301 and 302 is higher when the voltage of the capacitor rises than when the capacitor voltage falls.

Although in the oscillation circuits of embodiments 2 and 3 the output of the toggle flip flop circuit 209 is inverted at rising edges of the signal input to the trigger input terminal, but it may be inverted at falling edges.

The oscillation circuit of the present invention is advantageously capable of supplying a signal with stable cycles even in the presence of noise and is useful as, for example, an oscillation circuit for supplying a signal with stable cycles to a semiconductor integrated circuit.

What is claimed is:

1. An oscillation circuit, comprising:
first and second capacitors which are charged or discharged by a current generated by a constant current source;
a first comparator for comparing a first voltage which is determined according to the amount of charge stored in the first capacitor with a first reference voltage to output a first signal indicative that the first voltage has reached the first reference voltage;
a second comparator for comparing a second voltage which is determined according to the amount of charge stored in the second capacitor with a second reference voltage to output a second signal indicative that the second voltage has reached the second reference voltage;
an RS flip flop circuit which is shifted to a set state by one of the first signal and the second signal and shifted to a reset state by the other signal;
a first charge/discharge control circuit for controlling the first capacitor such that, when the RS flip flop circuit is in the set state, the first capacitor is in a charge state, and when the RS flip flop circuit is in the reset state, the first capacitor is in a discharge state; and
a second charge/discharge control circuit for controlling the second capacitor such that, when the RS flip flop circuit is in the reset state, the second capacitor is in a charge state, and when the RS flip flop circuit is in the set state, the second capacitor is in a discharge state.

2. An oscillation circuit, comprising:
first and second capacitors which are charged or discharged by a current generated by a constant current source;
a first comparator for comparing a first voltage which is determined according to the amount of charge stored in the first capacitor with a first reference voltage to output a first signal indicative that the first voltage has reached the first reference voltage;
a second comparator for comparing a second voltage which is determined according to the amount of charge stored in the second capacitor with a second reference voltage to output a second signal indicative that the second voltage has reached the second reference voltage;
a first RS flip flop circuit which is shifted to the set state when the first signal is output by the first comparator and which is shifted to the reset state when the second signal is output by the second comparator while the first RS flip flop circuit is in the set state;
a second RS flip flop circuit which is shifted to the set state when the second signal is output by the second comparator and which is shifted to the reset state when the first signal is output by the first comparator while the second RS flip flop circuit is in the set state;
a toggle flip flop circuit whose output is inverted when the first RS flip flop circuit shifts from the reset state to the set state and when the second RS flip flop circuit shifts from the reset state to the set state; and
a charge/discharge control circuit which selectively switches according to an output of the toggle flip flop circuit between a mode where the first capacitor is charged and the second capacitor is discharged and a mode where the first capacitor is discharged and the second capacitor is charged.

3. The oscillation circuit of claim 2, wherein:
the set state is a state where an output is high level;
the reset state is a state where an output is low level;
the oscillation circuit further comprises
a first one-shot circuit which outputs a first pulse signal of high level when an output of the first RS flip flop circuit rises,
a second one-shot circuit which outputs a second pulse signal of high level when an output of the second RS flip flop circuit rises, and
a logical sum circuit which outputs a logical sum of the first pulse signal and the second pulse signal; and
the output of the toggle flip flop circuit is inverted at a rising or falling edge of the output of the logical sum circuit.

4. An oscillation circuit, comprising:
any one of a charge-based first capacitor/comparator set and a discharge-based first capacitor/comparator set; and
any one of a charge-based second capacitor/comparator set and a discharge-based second capacitor/comparator set, wherein
the charge-based first capacitor/comparator set includes
a first capacitor which is charged by a current generated by a constant current source, and
a first comparator which outputs a first signal during a period extending from a time when a voltage determined according to the amount of charge stored in the first capacitor is increased to a first reference voltage by the charging of the first capacitor to a time when the voltage decreases to a second reference voltage which is lower than the first reference voltage,
the discharge-based first capacitor/comparator set includes
a first capacitor which is discharged by a current generated by a constant current source, and
a first comparator which outputs a first signal during a period extending from a time when a voltage determined according to the amount of charge stored in the first capacitor is decreased to a first reference voltage by the discharging of the first capacitor to a time when the voltage increases to a second reference voltage which is higher than the first reference voltage,
the charge-based second capacitor/comparator set includes
a second capacitor which is charged by a current generated by a constant current source, and
a second comparator which outputs a second signal during a period extending from a time when a voltage determined according to the amount of charge stored in the second capacitor is increased to a third reference voltage by the charging of the second capacitor to a time when the voltage decreases to a fourth reference voltage which is lower than the third reference voltage,
the discharge-based second capacitor/comparator set includes
a second capacitor which is discharged by a current generated by a constant current source, and
a second comparator which outputs a second signal during a period extending from a time when a voltage determined according to the amount of charge stored in the second capacitor is decreased to a third reference voltage by the discharging of the second capacitor to a time when the voltage increases to a fourth reference voltage which is higher than the third reference voltage, and
the oscillation circuit further comprises
a toggle flip flop circuit whose output is inverted every time any of the first signal and the second signal is output, and
a charge/discharge control circuit which selectively switches according to an output of the toggle flip flop circuit between a mode where the first capacitor is charged and the second capacitor is discharged and a mode where the first capacitor is discharged and the second capacitor is charged.

5. The oscillation circuit of claim 1, wherein the first and second capacitors are charged or discharged by a current generated by a common constant current source.

6. The oscillation circuit of claim 2, wherein the first and second capacitors are charged or discharged by a current generated by a common constant current source.

7. The oscillation circuit of claim 4, wherein the first and second capacitors are charged or discharged by a current generated by a common constant current source.

8. The oscillation circuit of claim 1, wherein:
when charging the first capacitor, the first charge/discharge control circuit couples an end of the first capacitor with a constant current source, and when charging the second capacitor, the second charge/discharge control circuit couples an end of the second capacitor with a constant current source; and
when discharging the first capacitor, the first charge/discharge control circuit causes a short-circuit between both ends of the first capacitor, and when discharging the second capacitor, the second charge/discharge control circuit causes a short-circuit between both ends of the second capacitor.

9. The oscillation circuit of claim 2, wherein:
the charge/discharge control circuit charges each of the first and second capacitors by coupling an end of the capacitor with a constant current source; and
the charge/discharge control circuit discharges each of the first and second capacitors by causing a short-circuit between both ends of the capacitor.

10. The oscillation circuit of claim 4, wherein:
the charge/discharge control circuit charges each of the first and second capacitors by coupling an end of the capacitor with a constant current source; and
the charge/discharge control circuit discharges each of the first and second capacitors by causing a short-circuit between both ends of the capacitor.
